(19) United States
(12) Patent Application Publication
(10) Pub. No.: US 2004/0159949 A1
(43) Pub. Date: Aug. 19, 2004

(54) Semiconductor device and method of manufacturing the same

(76) Inventor: Hideaki Nii, Yokohama-shi (JP)

Correspondence Address: FROMMER LAWRENCE & HAUG, 745 FIFTH AVENUE- 10TH FL., NEW YORK, NY, 10151, US

(21) Appl. No.: 10/427,878

(22) Filed: May 1, 2003

(30) Foreign Application Priority Data
Feb. 13, 2003 (JP) 2003-035567

(51) Int. Cl. H01L 23/48

(52) U.S. Cl. 257/758

(57) ABSTRACT

A semiconductor device includes a substrate, and an element isolating insulating film provided in the substrate so as to isolate a device region. A first gate insulating film and a second gate insulating film having a film thickness greater than the first gate insulating film are provided on the substrate in the device region. A gate electrode includes a first part extending in a first direction on the first gate insulating film, and a second part extending from the first part in a second direction different from the first direction. A portion of the gate electrode where an internal angle is formed by the first and second parts is provided on the second gate insulating film. Source/drain diffusion layers are formed in the substrate so that a channel layer under the first part of the gate electrode is held between the source/drain diffusion layers.

### CROSS-REFERENCE TO RELATED APPLICATIONS

This application is based upon and claims the benefit of priority from the prior Japanese Patent Application No. 2003-035567, filed Feb. 13, 2003, the entire contents of which are incorporated herein by reference.

### BACKGROUND OF THE INVENTION

1. Field of the Invention

The present invention relates to a semiconductor device. In particular, the present invention relates to a MIS (Metal Insulator Semiconductor) type semiconductor device using an SOI (Silicon On Insulator) device formed in a semiconductor layer on an insulating film.

2. Description of the Related Art

Concurrent with ever increasing developments in low power consumption and high density semiconductor integrated circuits, the following demands are made. That is, it is required to micro-fabricate individual devices constituting these integrated circuits, and to make low the operating voltage. In order to meet the above demands, there has been known an SOI device, which is capable of achieving both high-speed operation and low power consumption.

FIG. 12A and FIG. 12B schematically show a typical SOT device. As shown in FIG. 12A and FIG. 12B, a MIS transistor Q is formed in a semiconductor layer 103 provided on a semiconductor substrate 101 via an insulating film 102. The gate electrode G is formed into the letter T shape. This is because the gate electrode G is used as the boundary between a region 106 where contact into the semiconductor layer 103 is formed and a source-drain diffusion layers S, D when implanting ions having a polarity different from each other.

FIG. 13 schematically shows the method of manufacturing the SOI device shown in FIG. 12A and FIG. 12B. As depicted in FIG. 13, the insulating film 102 and the semiconductor layer 103 are formed on the semiconductor substrate 101; thereafter, the semiconductor layer 103 is removed except the position corresponding to a device region. An element isolating insulating film 104 is formed on the insulating film 102 at the portion already removed. A gate insulating film 105 is formed on the semiconductor layer 103 in the device region. A material film for the gate electrode G is deposited on the gate insulating film 105.

The material film for the gate electrode G is patterned by a lithography process and RIE (Reactive Ion Etching), and thereby, a gate electrode is formed.

As seen from FIG. 12A and FIG. 12B, a source/drain diffusion layers (not shown), interlayer insulating film 106, contact C, and interconnect layer 107 are formed.

The gate electrode G has a bent portion because it is formed into a T shape, as described above. For this reason, in the above RIE used for patterning the gate electrode G, plasma easily concentrates on portions forming the internal angle of the above bent portion. In the above portions, the etching rate becomes higher, and thus the gate insulating film 105 is removed, and in addition, the semiconductor layer 103 is etched. In particular, if polysilicon is used as the gate electrode G and silicon is used as the semiconductor layer 103, the above problem is further exacerbated because these materials have the same etching rate. Thus, if the semiconductor layer 103 is etched, the semiconductor device described above is regarded as being defective products; as a result, yield reduces.

Recently, in order to improve transistor performance, thickness reduction of the gate insulating film is advanced. However, if the gate insulating film is too thin, this causes the problem that off-state current and gate leak current increase.

### BRIEF SUMMARY OF THE INVENTION

According to a first aspect of the present invention, there is provided a semiconductor device comprising: a substrate; an element isolating insulating film provided in the substrate and isolating a device region; a first gate insulating film provided on the substrate in the device region; a second gate insulating film provided on the substrate in the device region, and having a film thickness greater than the first gate insulating film; a gate electrode including a first part extending in a first direction on the first gate insulating film and a second part extending from the first part in a second direction different from the first direction, a portion of the gate electrode where an internal angle is formed by the first and second parts being provided on the second gate insulating film; and source/drain diffusion layers formed in the substrate so that a channel layer under the first part of the gate electrode is held between the source/drain diffusion layers.

According to a second aspect of the present invention, there is provided a method of manufacturing a semiconductor device, comprising: forming an element isolating insulating film isolating a device region in a substrate; forming a first gate insulating film on the substrate in the device region; forming a second gate insulating film having a film thickness greater than the first gate insulating film on the substrate in the device region; forming a gate electrode including a first part extending in a first direction on the first gate insulating film and a second part extending from the first part in a second direction different from the first direction, a portion of the gate electrode where an internal angle is formed by the first and second parts being provided on the second gate insulating film; and forming source/drain diffusion layers in the substrate so that a channel layer under the first part of the gate electrode is held between the source/drain diffusion layers.

### BRIEF DESCRIPTION OF THE SEVERAL VIEWS OF THE DRAWING

FIG. 1 is a plan view schematically showing a semiconductor device according to a first embodiment of the present invention;

FIG. 2A is a cross-sectional view schematically showing the structure taken along a line IIA-IIA shown in FIG. 1;

FIG. 2B is a cross-sectional view schematically showing the structure taken along a line IIB-IIB shown in FIG. 1;

FIG. 3 is a cross-sectional view schematically showing the process of manufacturing the semiconductor device shown in FIG. 1, FIGS. 2A and 2B;

FIGS. 4, 5, 6, 7, 8, 9 and 10 are cross-sectional views schematically showing processes following FIG. 3;

FIG. 11 is a plan view schematically showing a semiconductor device according to a second embodiment of the present invention;

FIG. 12A is a plan view schematically showing a conventional semiconductor device;

FIG. 12B is a cross-sectional view schematically showing the structure taken along a line XIIB-XIIB shown in FIG. 12A; and

FIG. 13 is a cross-sectional view schematically showing the process of manufacturing the conventional semiconductor device shown in FIG. 12A.

### DETAILED DESCRIPTION OF THE INVENTION

Embodiments of the present invention will be described below with reference to the accompanying drawings. In the following description, the same reference numerals are given to constituent components having substantially the identical function and configuration, and the overlapping explanation will be made if necessary.

(First Embodiment)

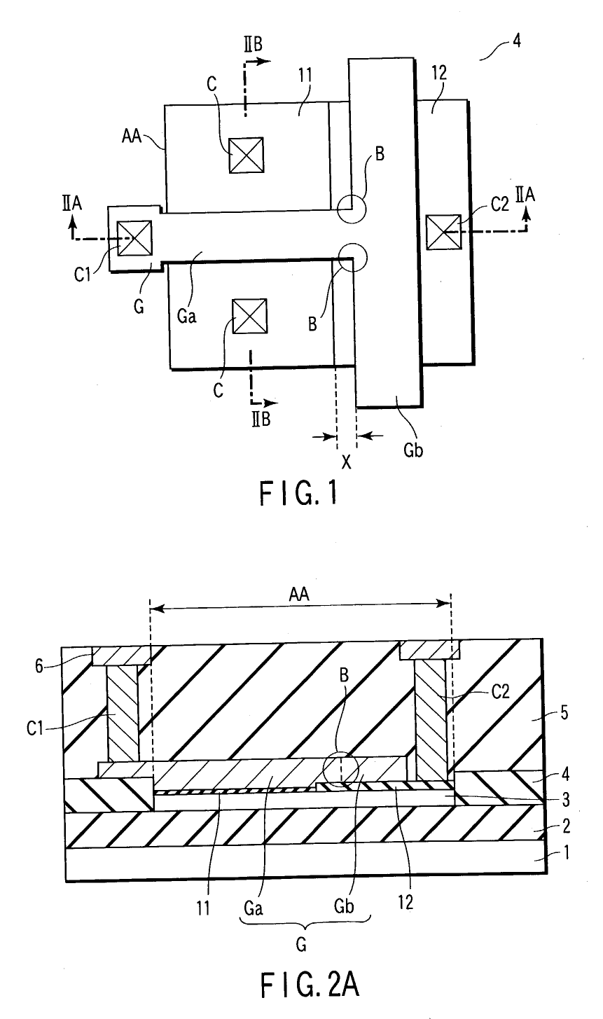

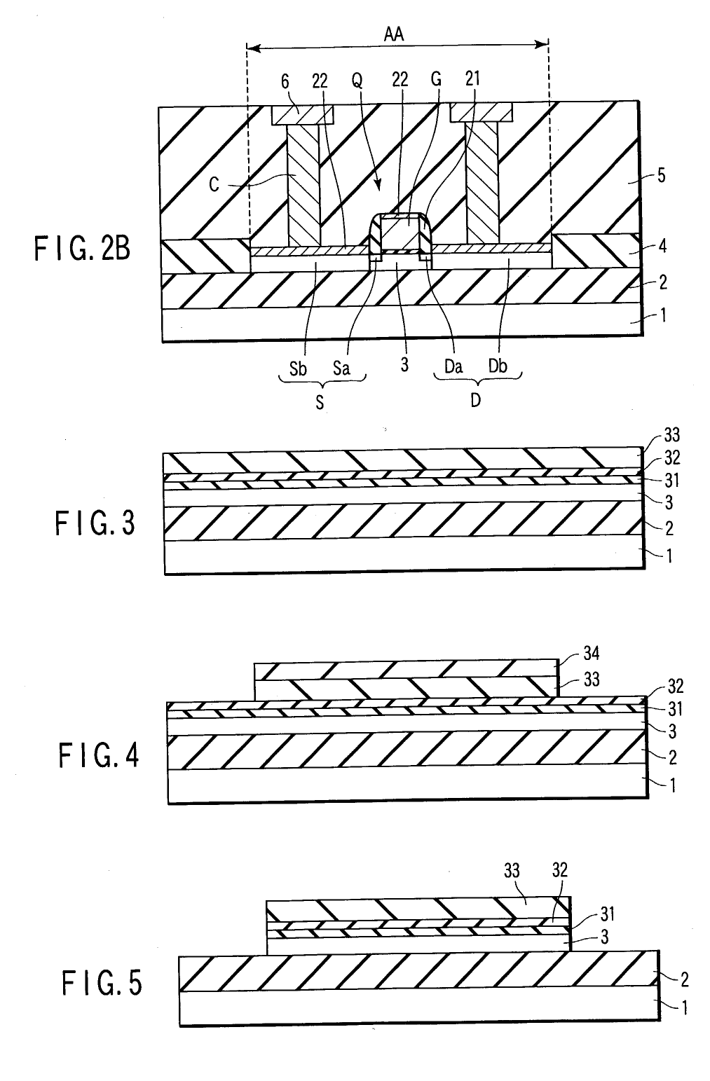

FIG. 1 is a plan view schematically showing a semiconductor device according to a first embodiment of the present invention. FIG. 2A and FIG. 2B are each cross-sectional views schematically showing cross sections taken along a line IIA-IIA shown in FIG. 1 and a line IIB-IIB shown in FIG. 1.

As depicted in FIG. 1, FIG. 2A and FIG. 2B, for example, an insulating film (Buried Oxide: BOX) 2 of silicon oxide is provided on a semiconductor substrate 1 of silicon. For example, a semiconductor layer 3 of single crystal silicon is formed on the insulating film 2. An element isolating insulating film 4 of, for example, silicon oxide is provided in the semiconductor layer 3 so that a device region AA surrounded by the element isolating insulating film 4 can be electrically isolated from other device regions (not shown).

A MIS (Metal Insulator Semiconductor) transistor Q is provided in the semiconductor layer 3 within the device region AA. The transistor Q is composed of a first gate insulating film 11, a second gate insulating film 12, a gate electrode G, a source diffusion layer S and a drain diffusion layer D.

The above first and second gate insulating films 11 and 12 are formed on the semiconductor layer 3. The second gate insulating film 12 has a film thickness greater than the first gate insulating films 11. More specifically, the first gate insulating film 11 has a thickness of 0.5 to 1.5 nm, for example. On the other hand, the second gate insulating films 12 has a film thickness greater than the first gate insulating film 12 by 0.3 to 2.0 nm, for example. Preferably, the second gate insulating films 12 has a film thickness greater than the first gate insulating films 12 by 0.3 to 0.8 nm. This is because the off-state current of the transistor Q increases if the second gate insulating film 12 is made too thick.

The gate electrode G is formed on the first and second gate insulating films 11 and 12. The gate electrode G has a first part Ga and a second part Gb. The first part Ga extends in the first direction (horizontal direction in FIG. 1); on the other hand, the second part Gb extends from the first part Ga in a second direction (vertical direction in FIG. 1) different from the above first direction. Typically, the gate electrode G has a letter T shape.

The first part Ga of the gate electrode G extends over part of the second gate insulating film 12 from the first gate insulating film 11, and functions as the gate electrode of the transistor Q. Portions forming the internal angle of the first part Ga and the second part Gb is provided on the second gate insulating film 12. Typically, the whole of second part Gb is provided on the second gate insulating film 12. A distance X between the end of the second part Gb of the gate electrode G and the end of the second gate insulating film 12 is set in the following manner. For example, the distance X is set in a range of 0.03 to 0.15 nm, considering alignment offset when forming the gate electrode G. Preferably, the distance X is set in a range of 0.03 to 0.08 nm.

The end of the gate electrode G extends on the element isolating insulating film 4, and is provided with contact C1 thereon. The side of the gate electrode G is provided with a sidewall insulating film 21. The source diffusion layer S and the drain diffusion layer D are provided so that the lower portion of the first part Ga of the gate electrode G in the semiconductor layer 3 can be held between these layers S and D. The source diffusion layer S and the drain diffusion layer D are composed of low concentration diffusion layers Sa, Da and high concentration diffusion layers Sb, Db, respectively. A silicide 22 is provided on the high concentration diffusion layers Sb, Db and the gate electrode G. A reference numeral C denotes each contact for the source diffusion layer S and drain diffusion layer D.

A contact C2 for controlling the potential of a channel region under the gate is provided on the semiconductor layer 3. The entire surface of the semiconductor device is covered with an interlayer insulating film 5.

The process of manufacturing the semiconductor device shown in FIG. 1, FIGS. 2A and 2B will be described below with reference to FIG. 3 to FIG. 10. FIG. 3 to FIG. 10 show successive processing in manufacturing the semiconductor device shown in FIG. 1, FIGS. 2A and 2B, and are cross-sectional views taken along a line IIA-IIA shown in FIG. 1.

As illustrated in FIG. 3, the insulating film 2 and the semiconductor layer 3 are formed on a semiconductor substrate 1 consisting of, for example, P-type silicon. A silicon oxide 31 is formed on the semiconductor layer 3 by thermal oxidation. Then, silicon nitride film 32 and silicon oxide film 32 are successively formed on the silicon oxide film 31 by employing LPCVD (Low Pressure Chemical Vapor Deposition) technique.

As seen from FIG. 4, a resist film 34 is formed at the region where the device region AA on the silicon oxide film 32 is formed, by employing a lithography process. Thereafter, the silicon oxide film 32 is patterned by dry etching such as RIE, using the resist film 34 as a mask.

As depicted in FIG. 5, after the resist film 34 is removed, the silicon nitride film 32, silicon oxide film 31 and semiconductor layer 3 are patterned by RIE using the silicon oxide film 32 as a mask.

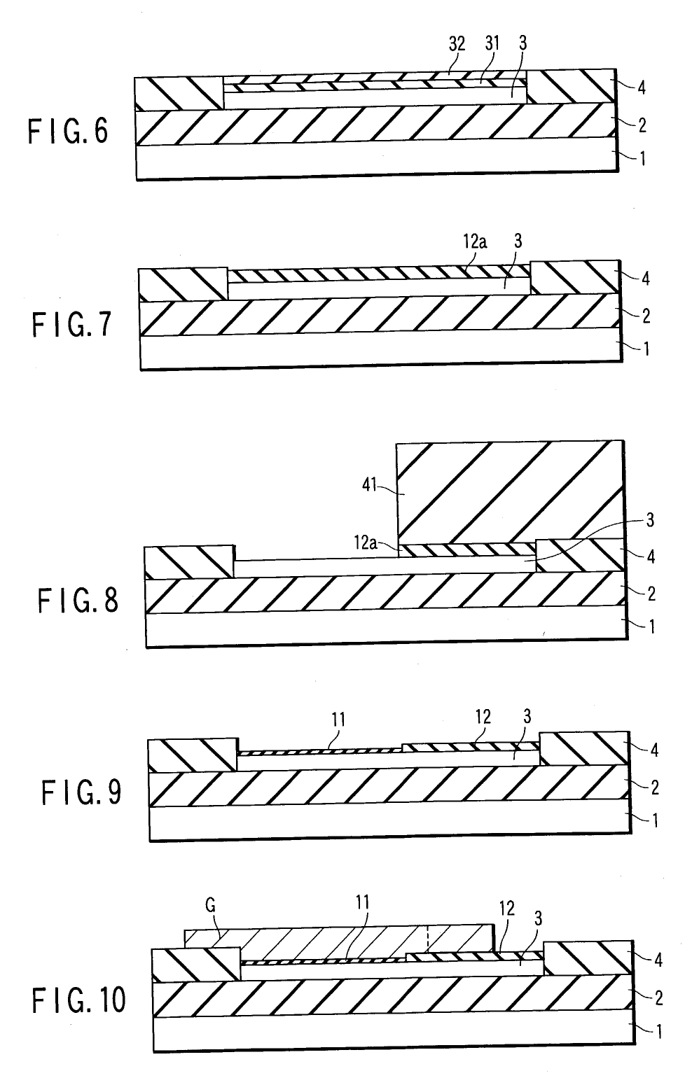

As illustrated in FIG. 6, after the silicon oxide film 33 is removed, a material film of the element isolating insulating film 4 is formed on the insulating film 2 by employing a CVD (Chemical Vapor deposition) technique. The above material film is polished until the silicon nitride film 32 is exposed using CMP (Chemical Mechanical Polishing). As a result, the element isolating insulating film 4 is formed.

The silicon nitride film 32 is removed by hot phosphoric acid. Then, impurities for controlling the threshold voltage of the transistor Q, for example, ions are implanted into the semiconductor layer 3 by ion implantation.

As seen from FIG. 7, a material film 12a of the second gate insulating film 12 is formed on the semiconductor layer 3 in the device region AA by thermal oxidation. The material film 12a has a film thickness greater than the first gate insulating film 11.

As shown in FIG. 8, a resist film 41 is formed so as to cover the region where the second gate insulating film 12 is formed. Then, the above material film 12a is partially removed using HF-based solution while using the resist film 41 as a mask.

As illustrated in FIG. 9, the resist film 41 is removed. The first gate insulating film 11 is formed by thermal oxidation, and thereby, the thickness of the material film 12a increases. As a result, the second gate insulating film 12 is formed.

As is depicted in FIG. 10, polysilicon is deposited on the entire surface of the semiconductor device by employing an LPCVD technique. Then, the gate electrode G having the shape shown in FIG. 1 is formed by a lithography process and RIE.

As shown in FIG. 2A and FIG. 2B, ion implantation is carried out using the gate electrode G, and thereby, the low concentration diffusion layers Sb and Db are formed. Then, the sidewall insulating film 21 is formed by an LPCVD and RIE. Thereafter, ions are implanted using the gate electrode G and the sidewall insulating film 21 as a mask, and thereby, the high concentration diffusion layers Sa and Da are formed.

A high melting point metal, such as Ti, Co or Ni are deposited on the surface of the semiconductor device, and subjected to heat treatment, thereby, the silicide 22 is formed. Using a standard interconnection forming technique, the interlayer insulating film 5, contacts C, C1, C2 and interconnection layer 6 are formed. Thereafter, interlayer insulating films and multi-layer interconnection layers are further formed if desired.

According to the first embodiment of the present invention, the semiconductor device includes the gate electrode G having the first part Ga and the second part Gb extending from the first part Ga in the direction different from the extending direction of the first part Ga. The portion B forming the internal angle of the first and second parts Ga and Gb is provided on the second gate insulating film 12 having the film thickness more than the first gate insulating film 11. Thus, when forming the gate electrode G by etching, the semiconductor layer 3 can be prevented from being etched in the portion B. Therefore, it is possible to prevent a reduction in yield.

In addition, the thickness of the gate insulating film (second gate insulating film 12) under the second part Gb of the gate electrode G is formed greater than in the conventional technique. Thus, the gate capacitance and gate leak current of the above-formed portion can be prevented from increasing. Therefore, it is possible to improve the performance of the transistor Q.

(Second Embodiment)

In the first embodiment, the present invention is applied to an SOI device. On the contrary, the second embodiment is applied to other semiconductor devices.

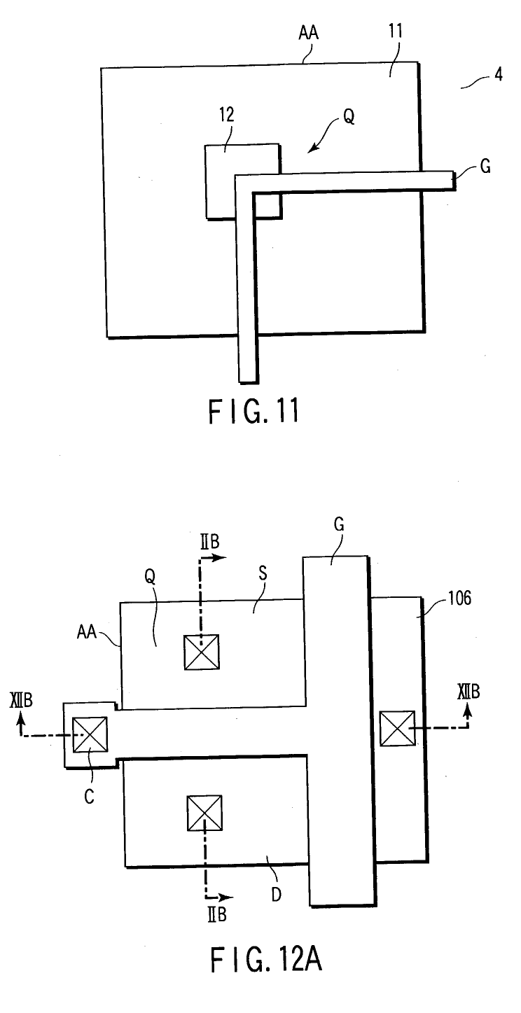

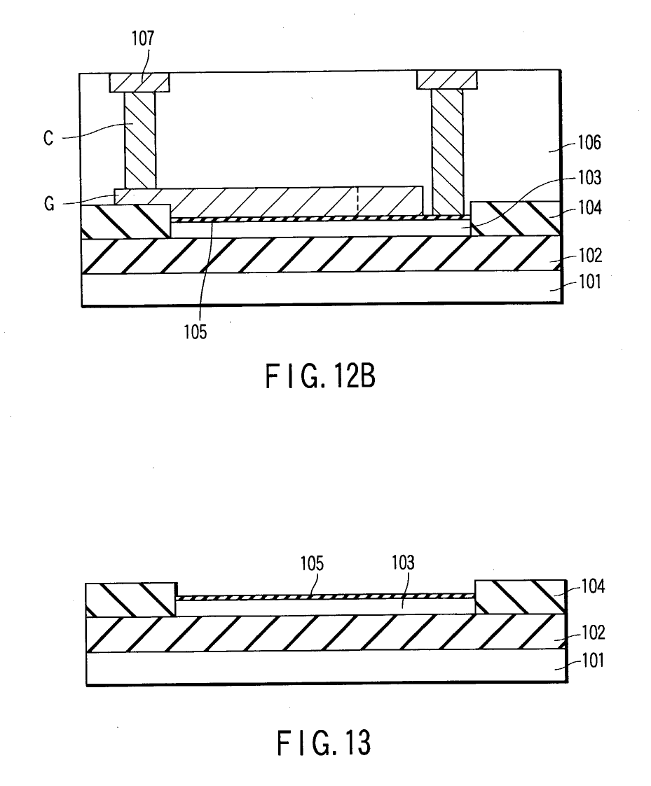

FIG. 11 is a plan view schematically showing a semiconductor device according to a second embodiment of the present invention. As is depicted in FIG. 11, the transistor Q is formed in the device region AA. The gate electrode G of the transistor Q has a bent portion, like the first embodiment. The gate insulating film (second gate insulating film) 12 around the portion forming the internal angle of the bent portion is formed greater than other gate insulating film (first gate insulating film) 11. Other structures are similar to those of standard transistors.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate;
an element isolating insulating film provided in the substrate and isolating a device region;
a first gate insulating film provided on the substrate in the device region;
a second gate insulating film provided on the substrate in the device region, and having a film thickness greater than the first gate insulating film;
a gate electrode including a first part extending in a first direction on the first gate insulating film and a second part extending from the first part in a second direction different from the first direction, a portion of the gate electrode where an internal angle is formed by the first and second parts being provided on the second gate insulating film; and
source/drain diffusion layers formed in the substrate so that a channel layer under the first part of the gate electrode is held between the source/drain diffusion layers.

2. The device according to claim 1, wherein the substrate includes:
a semiconductor substrate;
an insulating film provided on the semiconductor substrate; and
a semiconductor layer provided on the insulating film.

3. The device according to claim 1, wherein the second part is provided on the second gate insulating film.

4. The device according to claim 1, wherein the second gate insulating film has a film thickness 0.3 to 2.0 nm greater than that of the first gate insulating film.

5. The device according to claim 1, wherein the distance between an end of the second part and an end of the second gate insulating film is set to range from 0.03 to 0.08 nm.

6. A method of manufacturing a semiconductor device, comprising:
forming an element isolating insulating film isolating a device region in a substrate;
forming a first gate insulating film on the substrate in the device region;
forming a second gate insulating film having a film thickness greater than the first gate insulating film on the substrate in the device region;
forming a gate electrode including a first part extending in a first direction on the first gate insulating film and a second part extending from the first part in a second direction different from the first direction, a portion of the gate electrode where an internal angle is formed by the first and second parts being provided on the second gate insulating film; and
forming source/drain diffusion layers in the substrate so that a channel layer under the first part of the gate electrode is held between the source/drain diffusion layers.

7. The method according to claim 6, where forming the element isolating insulating film in a substrate includes:
providing an insulating film on a semiconductor;
forming a semiconductor layer on the insulating film; and
forming the element isolating insulating film in the semiconductor layer.

8. The method according to claim 6, wherein the second part is provided on the second gate insulating film.

9. The method according to claim 6, wherein the second gate insulating film has a film thickness 0.3 to 2.0 nm greater than that of the first gate insulating film.

10. The method according to claim 6, wherein the distance between an end of the second part and an end of the second gate insulating film is set to range from 0.03 to 0.08 nm.
